(19) United States
(12) Patent Application Publication
(10) Pub. No.: US 2011/0226334 A1
(43) Pub. Date: Sep. 22, 2011

(54) SOLAR MODULE SEALANT

(75) Inventors: Kathleen Lamb, Jackson, MI (US); Justin Eric Bates, Clark Lake, MI (US)

(73) Assignee: ADCO PRODUCTS. INC., Michigan Center, MI (US)

(21) Appl. No.: 13/128,917

(22) PCT Filed: Feb. 12, 2010
(86) PCT No.: PCT/US2010/024116

§ 371 Date: May 12, 2011

Related U.S. Application Data
(60) Provisional application No. 61/151,932, filed on Feb. 12, 2009.

(51) Int. Cl. H01L 31/0203; C08L 21/00; C08L 9/00; C08K 3/34; C08K 3/26; C08K 3/22; C08K 3/36; C08K 5/5445; C08K 5/1515; C08K 5/54; C08K 5/17

(52) U.S. Cl. 136/259; 524/570; 524/574; 524/451; 524/425; 524/430; 524/447; 524/188; 524/114; 524/81; 524/528; 524/186

(57) ABSTRACT

A sealant composition which may be applied between two substrates in a solar panel provides consistent rheology, high weatherability, acts as a moisture barrier, and has low conductivity. The sealant composition preferably includes a rubber component, at least one rheology modifier, an adhesion promoter, a flow modifier, a stabilizer, and a high level of carbon black.

### FIELD

The present invention relates to a solar module sealant, and more particularly to a sealant and adhesive composition employed between two substrates in a solar module that has consistent rheology control, low conductivity, low moisture vapor transmission, and high weatherability.

### BACKGROUND

Photovoltaic solar panels or modules generally include a photovoltaic cell that is laminated and/or sandwiched between a plurality of substrates. The majority of photovoltaic cells are rigid wafer-based crystalline silicon cells or thin film modules having cadmium telluride (Cd—Te), amorphous silicon, or copper-indium-diselenide (CuInSe₂) deposited on a substrate. The thin film photovoltaic modules may be either rigid or flexible. Flexible thin film cells and modules are created by depositing the photoactive layer and any other necessary substance on a flexible substrate. Photovoltaic cells are connected electrically to one another and to other solar panels or modules to form an integrated system.

Photovoltaic modules are required to meet specific criteria in order to withstand the environments in which they are employed. For example, photovoltaic modules must meet certain weatherability criteria in order to last against hail impact, wind and snow loads, they must be protected from moisture invasion, which may corrode metal contacts and components within the photovoltaic cell itself, and they must meet voltage leakage requirements. The weatherability and voltage leakage characteristics must specifically meet IEC 6646 and UL 1703 requirements.

Accordingly, there is a need in the art for adhesives and sealants employed within a solar module that meet criteria for weatherability, moisture vapor transmission, compatibility with photovoltaic cells, and low conductivity.

### SUMMARY

The present invention provides a sealant composition which may be applied between two substrates in a solar panel. The sealant composition provides sufficient weatherability, acts as a moisture barrier, and has low conductivity. Additionally, the sealant composition must have a balanced rheology such that the composition is pliable enough to be applied at an application temperature, but have limited to no movement when exposed to the range of temperatures it will experience in its lifetime.

In one aspect of the present invention, the sealant composition preferably includes a rubber component, at least one rheology modifier, an adhesion promoter, a flow modifier, a stabilizer, and a high level of carbon black.

In another aspect of the present invention, the sealant composition includes polyisobutylene, amorphous poly-alpha-olefin, hindered phenol, hindered amine light stabilizer, and aminosilane.

In yet another aspect of the present invention, the sealant composition includes amorphous fumed silica, precipitated silica, talc, clay, TiO₂, NiO₂, and/or other nano particles.

The sealant composition is preferably applied as a bead between a first substrate and a second substrate. The sealant composition and the substrates cooperate to form a chamber that houses a photovoltaic cell.

Further areas of applicability will become apparent from the description provided herein. It should be understood that the description and specific examples are intended for purposes of illustration only and are not intended to limit the scope of the present disclosure.

### DRAWINGS

FIG. 1 is a top view of an embodiment of a solar module having a border seal composition according to the principles of the present invention;

FIG. 2 is a cross-sectional view of a portion of an embodiment of a solar module having a border seal composition according to the present invention;

FIG. 3 is a cross-sectional view of a portion of another embodiment of a solar module having a border seal composition according to the present invention; and

FIG. 4 is a cross-sectional view of a portion of still another embodiment of a solar module having a border seal composition according to the present invention.

### DETAILED DESCRIPTION

The following description is merely exemplary in nature and is not intended to limit the present disclosure, application, or uses.

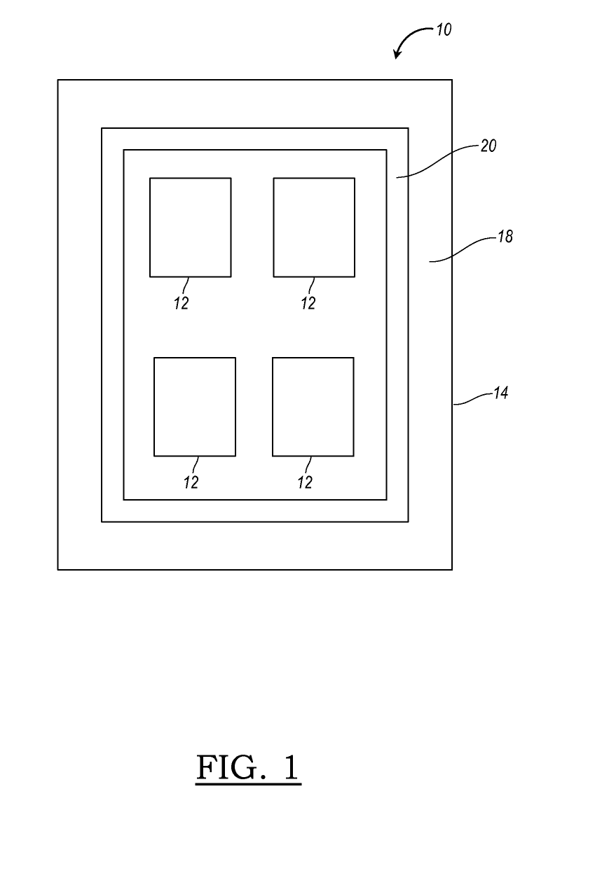

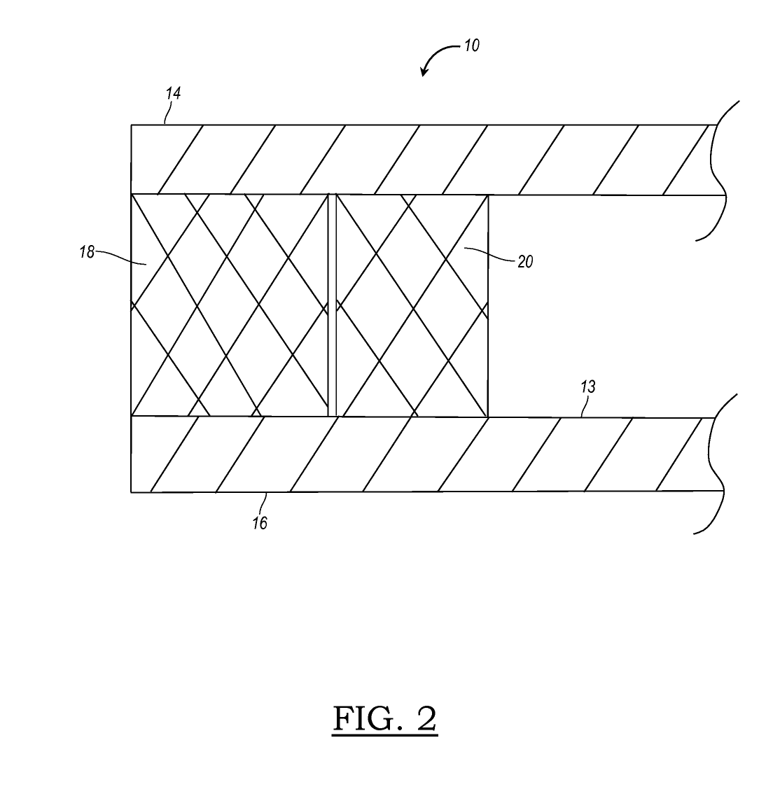

With reference to FIGS. 1 and 2, an exemplary solar module employing a sealant composition according to the principles of the present invention is generally indicated by reference number 10. The solar module 10 may take various forms without departing from the scope of the present invention and generally includes at least one photovoltaic cell 12 located within a chamber 13 defined by a first substrate 14 and a second substrate 16. While a plurality of photovoltaic cells 12 are illustrated, it should be appreciated that any number of photovoltaic cells 12 may be employed.

The photovoltaic cell 12 is operable to generate an electrical current from sunlight striking the photovoltaic cell 12. Accordingly, the photovoltaic cell 12 may take various forms without departing from the scope of the present invention. For example, the photovoltaic cell 12 may be a thin film cell with a layer of cadmium telluride (Cd—Te), amorphous silicon, or copper-indium-diselenide (CuInSe₂). Alternatively, the photovoltaic cell 12 may be a crystalline silicon wafer embedded in a laminating film or gallium arsenide deposited on germanium or another substrate.

The first substrate 14, or front panel, is formed from a material operable to allow wavelengths of sunlight to pass therethrough. For example, the first substrate 14 is glass or a plastic film such as polyvinylflouride. The second substrate 16, or back panel, is selected to provide additional strength to the solar module 10. For example, the second substrate 16 is a plastic.

The first and second substrates 14, 16 are adhered together by a first border seal 18 and a second border seal 20. The first border seal 18 is located near an edge of the solar module 10 between the first substrate 14 and the second substrate 16. The first and second border seals 18, 20 may be spaced apart or touching one another without departing from the scope of the present invention. Additionally, the border seals 18, 20 may have various widths. The first border seal 18 is operable to prevent moisture from entering the chamber 13 between the first and second substrates 14, 16. Accordingly, the first border seal 18 is comprised of, for example, a silicone, an MS polymer, a Silanated Polyurethane, a butyl component, or a polysulfide. The solar module 10 may also include a desiccant located loose within the chamber 13, between the seals 18 or 20, or within supports located between the substrates 14, 16. Alternatively, the desiccant may be located within the composition of the second border seal 20. A desiccant used in the border seal 20 may include, but is not limited to, a molecular sieve, such as, for example, Molsiv 3A from UOP, in an amount from about 5% to about 25% by weight of the composition of the border seal 20.

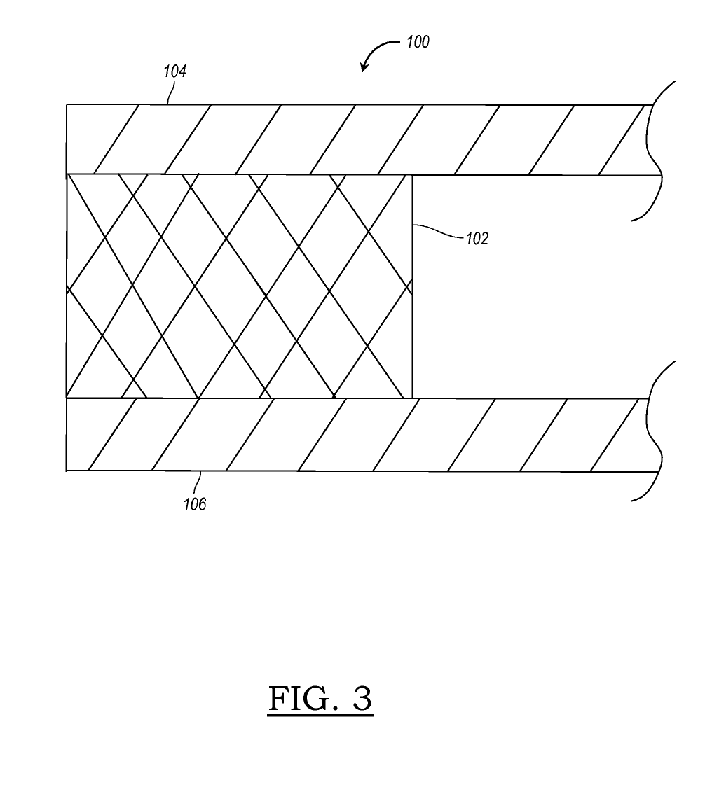

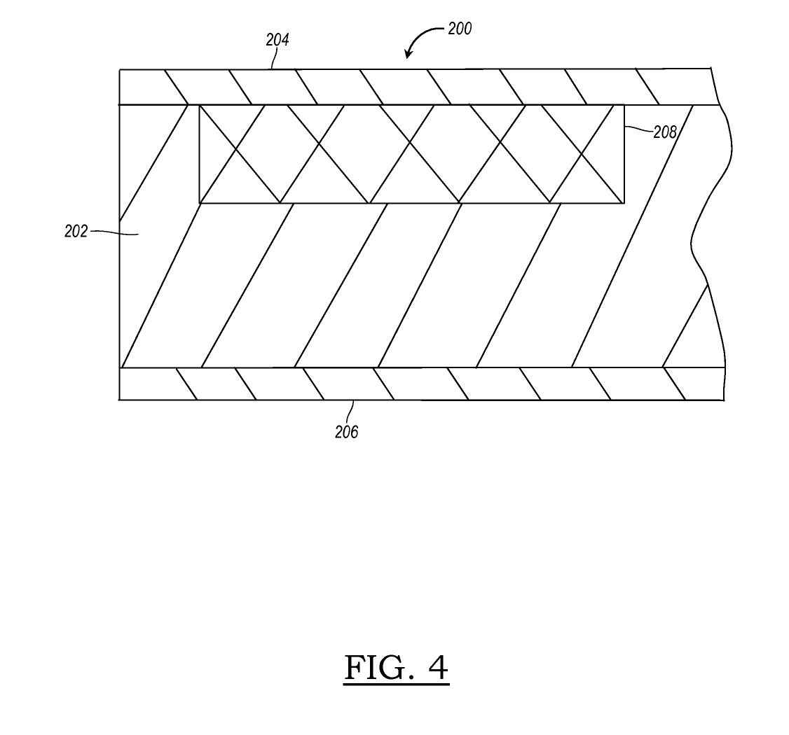

The second border seal 20 is operable to seal the chamber 13 that contains the photovoltaic cell 12. The second border seal 20 must have sufficient rheology control to maintain the distance between the first and second substrates 14, 16, have weatherability to withstand exposure to outside environments including prolonged ultra-violet radiation exposure, have low moisture vapor transmission (MVT), and have low conductivity. The second border seal 20 is comprised of a sealant composition having the unique characteristics of high weatherability and rheology control with low conductivity and MVT, as will be described in greater detail below. With reference to FIG. 3, an alternate embodiment of a solar module 100 is shown having a single border seal 102 between a first substrate 104 and a second substrate 106. The single border seal 102 is comprised of the sealant composition of the present invention and is used to replace the first border seal 18 illustrated in FIG. 2. With reference to FIG. 4, another alternate embodiment of a solar module 200 is shown having a laminate or non-reactive sheet 202 between a first substrate 204 and a second substrate 206. The laminate or sheet 202 supports a photovoltaic cell 208 between the first substrate 204 and the second substrate 206. The laminate or sheet 202 is comprised of the sealant composition of the present invention.

The solar modules 10, 100, and 200 described above may be formed using a vacuum lamination process. For example, regarding the solar module 10 described in FIGS. 1 and 2, the various layers of the photovoltaic module 10 including the photovoltaic cells 12, the first substrate 14, the second substrate 16, the first border seal 18, and the second border seal 20 are stacked during a lay-up step. Each layer is arranged as shown in FIGS. 1 and 2. Next, the assembly of stacked layers is vacuum sealed by a vacuum lamination machine. The vacuum seal is used to remove potential air bubbles from the solar module 10. The vacuum is preferably held for 5 to 7 minutes at 138 degrees Celsius. Finally, the solar module 10 is pressed or pressurized. The press is preferably held for approximately 15 minutes at 138 degrees Celsius. However, it should be appreciated that the timing and temperature during vacuum and press steps may vary without departing from the scope of the present invention.

The sealant composition of the present invention includes a rubber component, at least one rheology modifier, an adhesion promoter, a flow modifier, and a stabilizer. These components are balanced to produce a sealant having desirable sealing characteristics, high weatherability, desired rheology control, and low conductivity.

The rubber component is preferably polyisobutylene having average viscosity and a molecular weight (MW) of approximately 55,000. The polyisobutylene is operable as a barrier against moisture. Alternative rubbery components that may be employed in the composition include ethylene propylene rubber, butyl rubber, ethylene propylene diene rubber, low and medium molecular weight polyisobutylene (75,000 to 400,000 MW), and block copolymers with saturated mid-blocks. The rubber component is included in the composition in an amount of about 40% to about 80% by weight and in a preferred embodiment from about 60% to about 65% by weight.

The rheology modifiers preferably include, but are not limited to, a form of carbon black and one or more components selected from a group consisting of amorphous fumed silica, precipitated silica, and talc.

The carbon black may be coated and contain particles of various sizes. The carbon black functions as a UV absorber resulting in reduction in degradation of polymer components within the composition. The carbon black also aids in preventing oxidation of the polymers due to heat exposure. Various grades of carbon black may be selected, but are preferably optimized for low conductivity. The carbon black may be included in the composition in an amount from about 2% to about 25% by weight and in one preferred embodiment in an amount of about 4% to about 7% by weight and in another preferred embodiment in an amount of about 10% to about 21% by weight. The amount of carbon black can be increased while maintaining low conductivity if the carbon black has been manufactured with a post oxidation process that changes the surface chemistry on the carbon black particles. The pH is typically lower due to the presence of oxidized groups. For example, Nerox 2500 from Evonik may be employed. Additionally, the size and structure of the carbon black that is employed can also affect the conductivity. More specifically, carbon black selected with larger particle size and lower structure (i.e. lower aggregate branching due to carbon black particulate fusing) favors lower conductivity.) The purpose of a high carbon black content in a sealant is to make the mixture particularly stable toward high temperatures and UV irradiation. If the carbon black content were to be substantially reduced because of the volume resistivity, this would no longer be the case, and the sealing compound would no longer show the required long-term stability for applications in the field of solar modules, i.e. for applications involving high temperatures and solar radiation. By using a special carbon black in place of the carbon blacks generally used in sealants, however, it is possible to obtain a compound that has all the required properties. Accordingly, selecting an oxidatively post-treated Carbon black made by the furnace process and having a primary-particle size in the 50-60 nm range, a carbon black had been found which not only permitted filler contents of up to and exceeding 20 wt. % for the compound, which are necessary for stabilization, mechanical reinforcement and viscosity regulation, but simultaneously result in a low conductivity.

The amorphous fumed silica provides rheology control and helps prevent the sealant composition from flowing or sagging during application and lifetime use. The amorphous fumed silica may alternatively be replaced or supplemented with hydrophobic silane treated fumed silica with a surface area from about 100 to about 300 m²/gm. The amorphous fumed silica may be included in the composition in an amount from about 1% to about 10% by weight, and in a preferred embodiment in an amount of about 2% to about 6% by weight.

The precipitated silica also provides rheology control and helps prevent the sealant composition from flowing or sagging during application and lifetime use. Moreover, the amorphous fumed silica lowers conductivity by lowering the carbon black connectivity. The precipitated silica may be included in the composition in an amount from about 1% to about 10% by weight, and in a preferred embodiment in an amount of about 2% to about 6% by weight.

The talc provides rheology control and helps prevent the sealant composition from flowing or sagging during application and lifetime use. Moreover, the talc lowers conductivity by lowering the carbon black connectivity. The talc may alternatively be replaced or supplemented with precipitated calcium carbonate, ground calcium carbonate, TiO₂, NiO₂, or various types of clay such as bentonite or kaolin, or with other nano particles. The talc may be included in the composition in an amount from about 2% to about 25% by weight, and in a preferred embodiment in an amount of about 7% to about 15% by weight.

The adhesion promoter preferably includes, but is not limited to, aminosilane. Alternative adhesion promoters that may be employed in the composition include epoxy silanes and vinyl silanes. The adhesion promoter is included in the composition in an amount of about 0.2% to about 1.5% by weight and in a preferred embodiment from about 0.2% to about 0.5% by weight.

The flow modifier preferably includes, but is not limited to, amorphous poly-alpha-olefin. The amorphous poly-alpha-olefin provides additional strength and rigidity to the sealant composition and also aids in application of the sealant composition by reducing viscosity of the sealant at elevated dispensing temperatures (e.g., 110-150 degrees Celsius). Alternative flow modifiers that may be employed in the composition include partially crystalline grades of amorphous poly-alpha-olefin, butyl and/or ethylene rich amorphous poly-alpha-olefin, and polyethylene. The flow modifier is included in the composition in an amount of about 2% to about 25% by weight and in a preferred embodiment from about 10% to about 15% by weight.

The stabilizer preferably includes an antioxidant and hindered amine light stabilizer. The antioxidant protects the polymers in the composition during the manufacturing process, application process, and provides protection of the sealant over the lifetime use. The antioxidant is preferably a hindered phenol, though various other kinds and types of antioxidants may be employed. The antioxidant may be included in the composition in an amount of about 0.5% to about 1.5% by weight and in a preferred embodiment in an amount of about 0.5% to about 1% by weight. The hindered amine light stabilizer provides additional UV protection and also functions synergistically with hindered phenol type antioxidants to provide additional heat stabilization to prevent degradation of polymers. The hindered amine light stabilizer may be alternatively replaced with various kinds of UV absorbers, or the hindered amine light stabilizer may be used in combination with a UV absorber. The hindered amine light stabilizer may be included in the composition in an amount of about 0.5% to about 3.0% by weight and in a preferred embodiment in an amount of about 0.5% to about 1% by weight. UV absorbers may be include in the composition in an amount from about 0.5% to about 3.0% by weight in combination with the hindered amine light stabilizer.

The sealant composition of the present invention is preferably prepared by mixing all of the components using an S-blade or Sigma blade mixer. The resulting sealant composition may be pumped onto a surface or substrate in the form of a bead using a hot melt apparatus such as a hot melt applicator, roll coater, or a similar apparatus. Alternatively, the sealant composition may be extruded into a sheet or other shape to support a photovoltaic cell, depending on the desired application.

In order that the invention may be more readily understood, reference is made to the following examples which are intended to illustrate various embodiments of the sealant composition of the present invention, but not limit the scope thereof:

### EXAMPLES

### Sealant Compositions and Test Results

| Exemplary | Exemplary Component | Percent by Weight (%) | | | |
|---|---|---|---|---|---|
| Trade Name | Description | Example 1 | | Example 2 | |
| Oppanol B12 | Polyisobutylene | 62.7 | | 58.8 | |
| Vestoplast 750 | APAO (amorphous poly-alpha-olefin) | 11.6 | | 10.9 | |
| Irganox 1010 | Antioxidant | 0.4 | | 0.4 | |
| Tinuvin 783 | HALS (hindered amine light | 0.5 | | 0.4 | |
| | stabilizer) | | | | |
| SCA-603 | Aminosilane | 0.2 | | 0.1 | |
| Aerosil 200 | Amorphous fumed silica | 5.7 | | 5.4 | |
| Hisil 233 | Precipitated silica | 2.3 | | 2.2 | |
| Mistron Vapor | Talc | 10.6 | | 9.9 | |
| Nerox 2500 | Carbon Black | 0 | | 11.9 | |
| Printex 30 | Carbon Black | 6.0 | | 0 | |
| | TOTAL: | 100.00 | | 100.00 | |
| Press Flow Viscosity | | 6 | seconds | 6 | seconds |
| 16 hr Flow | | 0.101 | in | 0.079 | in |
| Current Leakage | | 0.00 | μA | 0.00 | μA |
| Resistance | | >500 | Mohm | >500 | Mohm |
| Dielectric | | 7.5 | kV | 8.5 | kV |
| Breakdown | | | | | |

### ADDITIONAL EXAMPLES

### Sealant Compositions and Test Results

| Exemplary | Exemplary Component | Percent by Weight (%) | | | |
|---|---|---|---|---|---|
| Trade Name | Description | Example 3 | Example 4 | | |
| Oppanol B12 | Polyisobutylene | 56.0 | 53.3 | | |
| Vestoplast 750 | APAO (amorphous poly-alpha-olefin) | 10.4 | 9.9 | | |
| Irganox 1010 | Antioxidant | 0.4 | 0.4 | | |
| Tinuvin 783 | HALS (hindered amine light | 0.4 | 0.4 | | |
| | stabilizer) | | | | |
| SCA-603 | Aminosilane | 0.1 | 0.1 | | |
| Aerosil 200 | Amorphous fumed silica | 5.2 | 4.9 | | |
| Hisil 233 | Precipitated silica | 2.1 | 2.0 | | |
| Mistron Vapor | Talc | 9.4 | 9.0 | | |
| Nerox 2500 | Carbon Black | 16.0 | 20.0 | | |
| Printex 30 | Carbon Black | 0 | 0 | | |
| | TOTAL: | 100.00 | 100.00 | | |
| Press Flow Viscosity | | 7 | seconds | 6 | seconds |
| 16 hr Flow | | 0.070 | in | N/A | |
| Current Leakage | | 0.00 | μA | 0.3 | μA |
| Resistance | | >500 | Mohm | >100 | Mohm |
| Dielectric | | 6.0 | kV | 5.0 | kV |
| Breakdown | | | | | |

It should be appreciated that the exemplary trade name materials referenced are for illustration purposes only, and that suitable equivalent manufacturers may be employed.

The sealant composition of the present invention exhibits high weatherability, consistent rheology control, low MVT, as well as low conductivity and low acidity.

The composition of the present invention exhibits less than 20% change in overall dimensions, and more specifically exhibits less than 5% to 10% change in overall dimensions.

As noted above, the sealant composition must have a rheology that is pliable at application temperatures and which has limited movement at lifetime temperatures. The lifetime temperature range is from about −40 to 85 degrees Celsius. The rheology of the sealant composition is defined using the viscosity, modulus (storage and loss), and creep/recovery properties as a function of UV exposure (e.g., 3×4″ units of the sealant composition exposed to UVA—340 nm @ 1.35 W/m² intensity @ 85 degrees Celsius). Degradation of the sealant composition is defined as a significant change of these properties as samples see prolonged exposure to the above conditions. The sealant composition of the present invention does not see degradation of the rheology control under specific testing. In other words, the sealant composition of the present invention maintains consistent rheology control over the life of the solar module, for example, 25 to 30 years. The rheology may be tested for complex viscosity measurement, frequency sweep, and rotational creep. The method for testing complex viscosity measurement includes using a press to compress a sample material from un-extruded stock to 3 mm. Then, the sample is allowed to relax for at least 24 hours. Then, a test sample is cut from the compressed material using a 25 mm die. The test sample is placed onto a 25 mm Al parallel plate of an AR 2000 rheometer, and the test sample is heated to a test temperature. Once the test temperature is obtained, the test sample is compressed to 2 mm, excess material is trimmed, and the test begins. First, conditions are sampled for 5 minutes at test temperature. The test parameters are as follows: Gap: 2 mm; Stress Sweep: 0.03 Pa to 3000 Pa; Frequency: 1 Hz; Temperature: 85° C. and 130° C. The test yields Complex Viscosity in Pascal·sec (Pa·s) and Storage Modulus in Pascals (Pa). The composition of the present invention has less than 40% change of complex viscosity over the 20-30 years of simulated aging, with preferably less than 20% change, and more specifically less than 10% change.

The method for testing frequency sweep includes using a press to compress a sample material from un-extruded stock to 3 mm. Then, the sample is allowed to relax for at least 24 hours. Then, a test sample is cut from the compressed material using a 25 mm die. The test sample is placed onto a 25 mm Al parallel plate of an AR 2000 rheometer, and the test sample is heated to a test temperature. Once the test temperature is obtained, the test sample is compressed to 2 mm, excess material is trimmed, and the test begins. First, conditions are sampled for 5 minutes at test temperature. The test parameters are as follows: Gap: 2 mm; Frequency Sweep: 1 to 100 Hz; Constant Strain: 2×10⁻⁴; Temperature: 85° C. and 130° C. The test yields Complex Viscosity in Pascal·sec (Pa·s) and Storage Modulus in Pascals (Pa). The composition of the present invention has less than 40% change of both complex viscosity and storage modulus over the 20-30 years of simulated aging, with preferably less than 20% change, and more specifically less than 10% change.

The method for testing rotational creep includes using a press to compress a sample material from un-extruded stock to 3 mm. Then, the sample is allowed to relax for at least 24 hours. Next, a test sample is cut from the compressed material using a 25 mm die. The test sample is placed onto a 25 mm Al parallel plate of an AR 2000 rheometer, and the test sample is heated to a test temperature. Once the test temperature is obtained, the test sample is compressed to 2 mm, excess material is trimmed, and the test begins. First, conditions are sampled for 5 minutes at test temperature. The test parameters are as follows: Gap: 2 mm; Constant Shear Stress: 100 sec; Constant Strain: 2×10⁻⁴; Temperature: 85° C. and 130° C. The test yields Creep Response Deformation (mrad). The composition of the present invention has less than 40% change over the 20-30 years of simulated aging, with preferably less than 20% change, and more specifically less than 10% change.

The simulated aging includes using Simulated Aging Tests per UL 1703 or IEC 61646. These include exposure of the composition to 85 degrees C. and 85% humidity for up to 5000 hours, thermal cycling of −40 C to 85 C for 200 cycles, a humidity freeze test of −40 C to 85 C with humidity control at 85 C at 85% at 10 cycles, QUV Aging at 85 C and an exposure of UVA 340 1.35 W/m² at 340 nm up to 30,000 hours. Preferably, the composition sample tested has a thickness of 0.050 inches between glass plates having a thickness of 3.9 mm.

Moisture Vapor Transmission Rate is measured by a MOCON tester using ASTM F-1249. The MVT rate of the composition of the present invention is preferably less than 0.7 g/m² per 24 hours, and optimally less than 0.3 g/m² per 24 hours.

The low conductivity of the sealant composition of the present invention is tested using ASTM D149 and ASTM D257. More specifically, a Type 4 test fixture as described in ASTM D149 is used to provide proper electrode contacts on the samples. All sample thicknesses are measured prior to performing any electrical testing using a standard micrometer. Conductivity properties are determined by applying a DC voltage of 2000V and using a megohm meter to measure current leakage and calculate resistance. The applied voltage of 2000V is chosen based on doubling the 500V rating indicated in IEC 61646 and then adding 1000V. A high voltage source is used to slowly increase voltage (˜100V/s) until electrical arc occurs through sample. The voltage at this point is noted as Breakdown Voltage. All materials are tested at 23° C. and 40% humidity. The Breakdown Voltage is then correlated to voltage leakage. The sealant composition of the present invention exhibits 8,000 volts/thickness Breakdown Voltage and greater than 500 Mohm resistance. The 8,000 volts/thickness correlates to a voltage leakage within the requirements of IEC 61646 and UL 1703. An exemplary ladder study of Breakdown Voltage for various additional embodiments using standard carbon black is shown below in Charts 1 and 2.

CHART 1

| Raw | Exam- | Exam- | Exam- | Exam- | Exam- |
|---|---|---|---|---|---|
| Material | ple A | ple B | ple C | ple D | ple E |
| Mistron | 10.5% | 10.1% | 9.6% | 9.2% | 8.8% |
| Elftex 8 | 4.0% | 8.0% | 12.0% | 16.0% | 20.0% |
| Hisil 233 | 4.6% | 4.4% | 4.2% | 4.1% | 3.9% |
| Aerosil 200 | 0.5% | 0.5% | 0.5% | 0.5% | 0.4% |
| Fluffy | | | | | |
| Aerosil 200 | 5.3% | 5.0% | 4.8% | 4.6% | 4.4% |
| VS | | | | | |
| SCA-603 | 0.2% | 0.2% | 0.1% | 0.1% | 0.1% |
| Silane | | | | | |
| Vestoplast | 11.6% | 11.1% | 10.6% | 10.1% | 9.6% |
| 750 | | | | | |
| Irganox | 0.4% | 0.4% | 0.4% | 0.4% | 0.4% |
| 1010 | | | | | |
| Tinuvin 783 | 0.5% | 0.5% | 0.4% | 0.4% | 0.4% |
| F-DL | | | | | |
| Oppanol B- | 62.5% | 59.9% | 57.3% | 54.7% | 52.0% |
| 12 | | | | | |
| Dielectric | 10,000 V | <2,000 V | <2,000 V | N/A | <2,000 V |
| Breakdown | | | | | |
| Resistance | >500M | Fail | Fail | N/A | Fail |
| @ 2000 V | ohm | | | | |

CHART 2

| Raw | Exam- | Exam- | Exam- | Exam- | Exam- |
|---|---|---|---|---|---|
| Material | ple F | ple G | ple H | ple I | ple J |
| Mistron | 10.4% | 10.3% | 10.2% | 10.0% | 9.9% |
| Elftex 8 | 5.0% | 6.0% | 7.0% | 9.0% | 10.0% |
| Hisil 233 | 4.6% | 4.5% | 4.5% | 4.4% | 4.3% |
| Aerosil 200 | 0.5% | 0.5% | 0.5% | 0.5% | 0.5% |
| Fluffy | | | | | |
| Aerosil 200 | 5.2% | 5.1% | 5.1% | 5.0% | 4.9% |
| VS | | | | | |
| SCA-603 | 0.2% | 0.2% | 0.2% | 0.1% | 0.1% |
| Silane | | | | | |
| Vestoplast | 11.4% | 11.3% | 11.2% | 11.0% | 10.8% |
| 750 | | | | | |
| Irganox | 0.4% | 0.4% | 0.4% | 0.4% | 0.4% |
| 1010 | | | | | |
| Tinuvin 783 | 0.5% | 0.5% | 0.5% | 0.4% | 0.4% |
| F-DL | | | | | |
| Oppanol B- | 61.8% | 61.2% | 60.5% | 59.2% | 58.5% |
| 12 | | | | | |
| Dielectric | N/A | 8,000 V | N/A | N/A | <2,000 V |
| Breakdown | | | | | |
| Resistance | N/A | >500M ohm | N/A | N/A | Fail |
| @ 2000 V | | | | | |

The composition of the present invention is compatible with the photovoltaic cell 12. More specifically, the composition will not affect the operation of the photovoltaic cell 12 if the composition comes in contact with the photovoltaic cell 12, either by solid contact, or by contact via a gas or liquid that is expelled from the composition during the operational lifetime.

The description of the invention is merely exemplary in nature, and variations that do not depart from the gist of the invention are intended to be within the scope of the invention. Such variations are not to be regarded as a departure from the spirit and scope of the invention.

We claim the following:

1. A sealant composition comprising:
a rubber component, wherein the rubber component is included in the composition in an amount from about 40% to about 80% by weight;
carbon black, wherein the carbon black is included in the composition in an amount from about 7% to about 25% by weight;
an adhesion promoter, wherein the adhesion promoter is included in the composition in an amount from about 0.2% to about 1.5% by weight;
a flow modifier; and
a stabilizer;
wherein the sealant composition exhibits approximately 8,000 volts/thickness of breakdown voltage.

2. The sealant composition of claim 1 wherein the rubber component is selected from the group consisting of polyisobutylene having an average viscosity molecular weight (Mw) of approximately 55,000, ethylene propylene rubber, butyl rubber, ethylene propylene diene rubber, polyisobutylene having an average viscosity molecular weight (Mw) of approximately 75,000, polyisobutylene having an average viscosity molecular weight (Mw) of approximately 400,000, and block copolymers with saturated mid-blocks.

3. The sealant composition of claim 1 wherein the rubber component is included in the composition in an amount from about 60% to about 65% by weight.

4. The sealant composition of claim 1 wherein the carbon black is included in the composition in an amount from about 16% to about 20% by weight.

5. The sealant composition of claim 1 wherein the carbon black includes oxidized groups from a post oxidation manufacturing process and having a primary-particle size from about 50 nm to about 60 nm.

6. The sealant composition of claim 1 further comprising rheology modifiers selected from a group consisting of amorphous fumed silica, precipitated silica, talc, hydrophobic silane treated fumed silica with a surface area from about 100 to about 300 m2/gm, precipitated calcium carbonate, ground calcium carbonate, TiO2, NiO2, bentonite, and kaolin.

7. The sealant composition of claim 6 wherein the amorphous fumed silica is included in the composition in an amount from about 1% to about 10% by weight.

8. The sealant composition of claim 6 wherein the amorphous fumed silica is included in the composition in an amount from about 2% to about 6% by weight.

9. The sealant composition of claim 6 wherein the precipitated silica is included in the composition in an amount from about 1% to about 10% by weight.

10. The sealant composition of claim 6 wherein the precipitated silica is included in the composition in an amount from about 2% to about 6% by weight.

11. The sealant composition of claim 6 wherein the talc is included in the composition in an amount from about 2% to about 25% by weight.

12. The sealant composition of claim 6 wherein the talc is included in the composition in an amount from about 7% to about 15% by weight.

14. The sealant composition of claim 1 wherein the adhesion promoter is selected from the group consisting of aminosilane, epoxy silanes and vinyl silanes.

15. The sealant composition of claim 1 wherein the adhesion promoter is included in the composition in an amount from about 0.2% to about 0.5% by weight.

16. The sealant composition of claim 1 wherein the flow modifier is selected from the group consisting of amorphous poly-alpha-olefin, partially crystalline grades of amorphous poly-alpha-olefin, butyl or ethylene rich amorphous poly-alpha-olefin, and polyethylene.

17. The sealant composition of claim 1 wherein the flow modifier is included in the composition in an amount from about 2% to about 25% by weight.

18. The sealant composition of claim 1 wherein the flow modifier is included in the composition in an amount from about 10% to about 15% by weight.

19. The sealant composition of claim 1 wherein the stabilizer includes an antioxidant and a hindered amine light stabilizer.

20. The sealant composition of claim 19 wherein the antioxidant is included in the composition in an amount from about 0.5% to about 1.5% by weight.

21. The sealant composition of claim 19 wherein the antioxidant is included in the composition in an amount from about 0.5% to about 1% by weight.

22. The sealant composition of claim 19 wherein the hindered amine light stabilizer is included in the composition in an amount from about 0.5% to about 3.0% by weight.

23. The sealant composition of claim 19 wherein the hindered amine light stabilizer is included in the composition in an amount from 0.5% to about 1% by weight.

24. The sealant composition of claim 1 further comprising an ultra-violet absorber included in the composition in an amount from about 0.5% to about 3.0% by weight.

25. An assembly comprising:
a first substrate;
a second substrate;
a solar cell located between the first substrate and the second substrate;
a first seal disposed between the first substrate and the second substrate, the first seal disposed along a periphery of the first substrate and the second substrate; and
a second seal disposed between the first substrate and the second substrate and disposed between the first seal and the solar module, the second seal having a composition comprising:
a rubber component;
carbon black having oxidized groups;
an adhesion promoter;
a flow modifier; and
a stabilizer;
wherein the sealant composition exhibits approximately 8,000 volts/thickness of breakdown voltage.

26. The solar module of claim 25 wherein the first border seal has a composition comprising a silicone, an MS polymer, a Silanated Polyurethane, a butyl, or a polysulfide.

27. The solar module of claim 25 further comprising a desiccant located between the first substrate and the second substrate.

28. The solar module of claim 25 wherein the oxidized groups of the carbon black are created in a post oxidation manufacturing process and have a primary-particle size from about 50 nm to about 60 nm.

29. A sealant composition comprising:
polyisobutylene, having an average viscosity molecular weight (Mw) of approximately 55,000 present in an amount from about 40% to about 80% by weight;
carbon black, present in an amount from about 10% to about 25% by weight;
amorphous fumed silica, present in an amount from about 1% to about 10% by weight;
precipitated silica, present in an amount from about 1% to about 10% by weight;
talc, present in an amount from about 2% to about 25% by weight;
aminosilane, present in an amount from about 0.2% to about 1.5% by weight;
amorphous poly-alpha-olefin, present in an amount from about 2% to about 25% by weight;
antioxidant, present in an amount from about 0.5% to about 1.5% by weight; and
hindered amine light stabilizer, present in an amount from about 0.5% to about 3.0% by weight;
wherein the sealant composition exhibits approximately 8,000 volts/thickness of breakdown voltage.
